(19) United States
(12) Patent Application Publication
(10) Pub. No.: US 2024/0427951 A1
(43) Pub. Date: Dec. 26, 2024

(54) METHOD AND TRANSPORT SYSTEM FOR TRANSPORTING LOADS FROM A REPOSITORY POSITION TO A TARGET REGION

(71) Applicant: TGW Logistics Group GmbH, Marchtrenk (AT)

(72) Inventor: Pascal MOELLER, Unterweitersdorf (AT)

(73) Assignee: TGW Logistics Group GmbH, Marchtrenk (AT)

(21) Appl. No.: 18/696,491

(22) PCT Filed: Sep. 29, 2022
(86) PCT No.: PCT/AT2022/060340

§ 371 Date: Jun. 6, 2024

(30) Foreign Application Priority Data
Sep. 30, 2021 (AT) A50778/2021

(51) Int. Cl. G06F 30/15; B65G 1/137; G05D 1/667; G05D 1/698; G05D 105/28

(52) U.S. Cl. CPC G06F 30/15; B65G 1/1371; G05D 1/667; G05D 1/6987; G05D 2105/28

(57) ABSTRACT

A method and a transport system transports unit loads from a source position to a target region by autonomous guided vehicles. In this process, a unit load is transported in accordance with a transport order from a source position to a waiting location by a guided vehicle, which waiting location is assigned to the target region in accordance with the order. If the target region is free from another guided vehicle, the unit load is deposited at one of the storage locations of the target region. Here, an assignment of a unit load to a vacant storage location is derived from the arrival of the autonomous guided vehicles in the target region.

The invention relates to a method for transporting unit loads from a source position to a target region by a plurality of autonomous guided vehicles in a travel area located between the source position and the target region.

Furthermore, the invention relates to a transport system for carrying out a method of the above-mentioned kind.

A method and a transport system of said kind are generally known. For example,

EP 3 591 487 A1 discloses, in this context, a transport system with a plurality of autonomous guided vehicles (AGVs), which receive a specified transport order and a specified transport route from a central control unit. The guided vehicles operate in an article store with multiple aisles and/or dead ends, in which the guided vehicles cannot pass one another. In a virtual image of the article store, virtual nodes are deposited at each of the aisle entries, at which virtual nodes it is queried whether a guided vehicle is located in the respective aisle. A guided vehicle travels into the aisle only if same is vacant.

Further, WO 2017/165873 A1 discloses a method for lining up robots which are determined for a target location, wherein it is established whether a first robot is occupying the target location. If a second robot that is determined for the target location is in a target zone located near the target location, the second robot is navigated to a waiting position, at which it waits until the first robot has left the target location.

It is a problem of the known methods that they follow relatively rigid rules and the guided vehicles are centrally managed and therefore have no, or only little, autonomy of decision. Known methods are therefore relatively inflexible with respect to unforeseen events, which results in loss of performance.

It is therefore an object of the invention to specify an improved method and transport system for transporting unit loads from a source position to a target region. In particular, such a method and transport system are to be able to respond flexibly to unforeseen events in order to avoid loss of performance whenever possible.

The object of the invention is achieved by a method for transporting unit loads from a source position to a target region by a plurality of autonomous guided vehicles in a travel area located between the source position and the target region. Here, the target region has multiple storage locations for a unit load each, and at least one waiting location for an autonomous guided vehicle, which waiting location is assigned to the target region, is arranged in the travel area. Here, the method comprises the following steps:
a) acquiring multiple transport orders, each of which contains a source position, from which a unit load is to be picked up, and a target region, in which the unit load is to be deposited, by an electronic control system, which comprises a control computer,
b) assigning a transport order each to an autonomous guided vehicle each,
c) picking up a unit load from the source position in accordance with the order, and transporting the unit load to a waiting location assigned to the target region in accordance with the order by the autonomous guided vehicle assigned to the respective transport order in step b),
d) verifying an accessibility status of the target region in accordance with the order, wherein the accessibility status is “unoccupied” if the target region is free from another autonomous guided vehicle,
e) entering the target region in accordance with the order by the assigned autonomous guided vehicle and depositing the unit load at a vacant storage location of the target region in accordance with the order, which storage location is assigned to the unit load, if the verification in step d) yields that the accessibility status is “unoccupied,”
f) exiting the target region in accordance with the order by the assigned autonomous guided vehicle,
   wherein steps c) to f) are carried out for multiple autonomous guided vehicles and
   wherein an assignment of a unit load to a vacant storage location is derived from the arrival of the autonomous guided vehicles in the target region.

The object of the invention is further achieved by a transport system for transporting unit loads, comprising
a plurality of autonomous guided vehicles,
an electronic control system, which comprises a control computer,
multiple source positions, at which unit loads can be provisioned,
a target region with multiple storage locations for a unit load each,
a travel area located between the source position and the target region, which travel area can be traveled on by the plurality of autonomous guided vehicles, and
at least one and waiting location for an autonomous guided vehicle, which waiting location is arranged in the travel area and assigned to the target region,
wherein the electronic control system is configured for acquiring multiple transport orders, each of which contain a source position, from which a unit load is to be picked up, and contain a target region, in which the unit load is to be deposited,
wherein the control computer or the guided vehicles are configured for performing an assignment of a transport order each to an autonomous guided vehicle each,
wherein the control computer or the guided vehicles are configured for verifying an accessibility status of the target region, wherein the accessibility status is “unoccupied” if the target region is free from another autonomous guided vehicle, and
wherein the guided vehicles are configured for
   i) picking up a unit load from the source position in accordance with the order and transporting it to a waiting location assigned to the target region in accordance with the order,
   ii) entering the target region in accordance with the order and depositing the unit load at a vacant storage location of the target region in accordance with the order, which storage location is assigned to the unit load, if the verification of the accessibility status yields that the accessibility status is “unoccupied,” wherein an assignment of a unit load to a vacant storage location is derived from the arrival of the autonomous guided vehicles in the target region, and
   iii) exiting the target region in accordance with the order.

In particular, the autonomous guided vehicles arrive at the target region in an unplanned order. In particular, an assignment of a unit load to a vacant storage location is derived only from the arrival of the autonomous guided vehicles in the target region, which takes place in an unplanned order.

In particular, after exiting the target region in accordance with the order, the assigned autonomous guided vehicle can execute a next order, in particular an order according to step a), yet it can also travel to a loading station, for example.

The proposed measures enable the method to be relatively flexible and not follow rigid rules. In addition, the guided vehicles have a relatively great autonomy of decision. Therefore, unforeseen events can be responded to in a flexible manner, for example if an autonomous guided vehicle has to come to an unplanned halt during transport of a unit load in order to avoid an imminent collision with another object. The free assignment of a unit load to a vacant storage location ensures that loss of performance due to such unforeseen events can be avoided, or at least attenuated.

In particular, the storage locations can be arranged next to one another and/or in succession and form a dead end.

Optionally, the transport orders can contain the unit load itself in addition to the source position and to the target position.

Advantageously, the assignment of the unit load to a vacant loading location is done in particular without sequencing, which means that no sequence is formed. The assigning of the unit load to a vacant storage location is essentially done such that the unit load of a first arriving guided vehicle is assigned to a first vacant storage location, the unit load of a second arriving guided vehicle is assigned to a second vacant storage location, and so forth. This means that the arrival of the guided vehicles in the target region does not necessarily follow a specified sequence, but the guided vehicles can also arrive in the target region in an unplanned order. In this context, “in an unplanned order” means that the control computer does not actively interfere with the procedures in the transport system in order to form a sequence of the guided vehicles. For example, an unscheduled halt of an autonomous guided vehicle is not followed by a correctional interference of the control computer in order to reinstate a potential sequence. Yet, evidently, other commands can be transmitted to the guided vehicles. If the guided vehicles arrive in the target region in an unplanned order, the assignment of a unit load to a vacant storage location can be derived from this order.

Advantageous designs and further advancements of the invention result from the subclaims as well as from the description in combination with the figures.

Advantageously, the acquiring of the transport orders is done by the control computer of the electronic control system. Alternatively, the control computer can create the transport orders, for example on the basis of customer orders or article requests in the target region.

In a preferred embodiment, the electronic control system comprises the control computer and an order-processing computer. Advantageously, the order-processing computer is connected to the control computer. The order-processing computer is preferably configured for acquiring customer orders and transmit them to the control computer. The transport orders can then be created by the control computer. Alternatively, the order-processing computer can be configured for acquiring the customer orders and creating transport orders on the basis of the customer orders. The order-processing computer can transmit the transport orders to the control computer.

Preferably, the travel area comprises a reservation position and a release position, both of which can be traveled over by the autonomous guided vehicles, wherein the control computer or the guided vehicles are configured for changing the accessibility status of the target region from “unoccupied” to “occupied” as a result of the reservation position being traveled over and changing it from “occupied” to “unoccupied” as a result of the release position being traveled over.

The reservation position and/or release position can comprise a pass-through sensor, for example a light barrier, a camera or a weight sensor, which acquires a passing through the respective position by the autonomous guided vehicle.

Advantageously, a joint reservation and release position is provided, which comprises both the release position and the reservation position. The release position and the reservation position can therefore be arranged at the same location and/or at overlapping locations.

It should be noted in this context that the reservation position and the release position cannot be infinitely small in reality. Accordingly, the term “reservation position” can be equivalently replaced by “reservation region” and the term “release position” can be equivalently replaced by “release region.”

It should further be noted that the arrival of the autonomous guided vehicles in the target region depends on the arrival of the autonomous guided vehicles at the reservation position. Accordingly, an assignment of a unit load to a vacant storage location is derived primarily from the arrival of the autonomous guided vehicles at the reservation position and only subsequently from the arrival in the target region. However, the order of the guided vehicles at the reservation position and in the target region is identical.

Advantageously, the target region has a maneuvering zone, which preferably protrudes into the travel area. In this manner, the access to the storage locations is kept clear and it is facilitated for an autonomous guided vehicle to exit the target region. It can be provided that the maneuvering zone can be traveled on also by other autonomous guided vehicles (i.e. not only the guided vehicles that are assigned to a transport order), provided that the maneuvering zone is vacant. Particularly preferably, the maneuvering zone comprises the reservation and/or release position. This enables the accessibility status to be changed when the maneuvering zone is entered or exited. It is also advantageous if the unit loads are deposited sequentially at the storage locations by the autonomous guided vehicles, preferably such that all storage locations can be occupied. In particular, the unit loads are deposited sequentially, starting with a storage location that is most remote from the maneuvering zone. With the help of the proposed measures, the target region can be completely occupied by unit loads.

It is favorable if a target region is assigned multiple waiting locations, which form a waiting line, and an autonomous guided vehicle travels to a vacant waiting location of the waiting line, in particular the vacant waiting location at the very front of the waiting line, or advances from a waiting location to a vacant waiting location next in line, in particular in a direction of the target region. In particular, this operation is carried out by the autonomous guided vehicle independently, i.e. without a control command of the control computer. In this case, the autonomous guided vehicle also independently carries out the verification as to whether the respective waiting location is vacant or occupied by another guided vehicle. For example, optical sensors (e.g. camera, laser scanner) or also ultrasonic sensors can be used to that end. Alternatively, the verification as to whether a waiting location is vacant or has become vacant can also be carried out by the control computer. In this case, the occupied status or a change of same is reported to the autonomous guided vehicle by the control computer, whereupon the autonomous guided vehicle travels to the respective vacant waiting location. This procedure is of advantage whenever the autonomous guided vehicle has no sensors for verifying an occupied status of a waiting location or a verification cannot be carried out by the autonomous guided vehicle for other reasons. For example, it can happen that the autonomous guided vehicle has no visual contact with the respective waiting location from its current location and a verification is not possible for this reason. In particular, this can happen if the waiting locations are located in different, e.g. structurally separate, areas or a waiting line runs around the corner of a building wall. With the help of the proposed measures, a waiting queue will form in front of the target region in both cases. Therefore, the target region can be occupied by unit loads in an efficient manner. The waiting list locations need not be arranged next to one another to that end. Here, it is preferably provided that the entering of the target region is done from the waiting location at the very front of the waiting line and/or first in line. Here, an advancing is done from a waiting location to the waiting location next in line in a direction of the waiting location first in line. Here, the waiting locations are preferably arranged such that the waiting location first in line is positioned closest to the target region and a waiting location last in line is most remote from the target region. Here, the term “remote” is not necessarily meant in a topological sense but primarily in terms of organization. The waiting locations of a waiting line can, but do not have to, abut on one another and can all, or in some cases, be spaced apart from one another.

It is favorable if the transport system has multiple waiting locations that are acquired in the control computer and are statically assigned to a target region. This enables the transport system to be operated with a relatively small control effort. Yet, it is also of advantage if the transport system has multiple waiting locations acquired in the control computer and dynamically assigned to a target region by the control computer or multiple waiting locations dynamically created by the autonomous guided vehicles. In this manner, the travel area can be used in an optimal manner, as waiting locations are generated only as and when needed. In particular, it can be provided that a section of the travel area has waiting locations over time that are temporarily assigned to different target regions. With respect to dynamically created waiting locations, it should furthermore be noted that the guided vehicles are assigned to a transport order and thus a target region, and therefore also the waiting location created by the respective guided vehicle is assigned to the respective target region.

It is also favorable if an autonomous guided vehicle independently accepts and autonomously carries out a transport order of the transport orders acquired in step a). This ensures that a high degree of decentralization (and therefore a low degree of required central control complexity) is achieved. Yet, alternatively, it can also be provided that an autonomous guided vehicle is assigned a transport order of the transport orders acquired in step a) by the control computer, which transport order is autonomously executed by the autonomous guided vehicle after receipt. In this manner, at least the allocation of the transport orders is centrally controlled, whereby the procedures in the transport system can be planned better.

In another embodiment variant, the storage locations of a completely occupied target region are re-occupied by unit loads only if the respective target region was first emptied completely. In this manner, a target region can be alternately released for or blocked against the access by the autonomous guided vehicles. A target region that is blocked for the autonomous guided vehicles, however, can be released for the access by workers in the transport system, for example so that the workers can remove unit loads from the target region. This renders the method particularly safe. A target region is “completely occupied” whenever any and all storage locations of the respective target region are each occupied by a unit load or no vacant storage location is accessible anymore. Accordingly, a target region is deemed “completely occupied” even if, while there are still vacant storage locations per se in the target region, these storage locations can no longer be reached because the route to them is blocked by (a) unit load(s). A target region is “completely emptied” whenever none of the storage locations of the respective target region is occupied by a unit load.

It is also of particular advantage if the transport system has multiple target regions, which are alternately occupied and emptied. This ensures that the procedures in the transport system are only slightly disturbed if a target region is alternately released for or blocked against the access by the autonomous guided vehicles.

In accordance with a first embodiment, an alternate filling of the target regions can be done such that a second target region is occupied only once the first target region is completely occupied. Accordingly, an alternate emptying of the target regions in accordance with the first embodiment can be done such that the second target region is emptied only once the first target region is completely emptied.

In accordance with a second embodiment, the alternate filling of the target regions can also be done such that the storage locations of different target regions are occupied alternately. In accordance with the second embodiment, also the alternate emptying of the target regions can be done such that the storage locations of the different target regions are emptied alternately. It can also be provided that the filling is done in accordance with the first embodiment and the emptying is done in accordance with the second embodiment or vice versa.

It is also particularly advantageous if virtual twins of the autonomous guided vehicles exist in a simulation environment on the control computer and at least the verification in accordance with step d) is executed in the simulation environment, and/or the simulation environment is at least configured for verifying the accessibility status of the target region. The virtual twins enable even complex control problems to be solved. In particular, the communication of autonomous guided vehicles, which have no way of communicating with one another in the real world, is enabled via their virtual twins.

It is also advantageous if the unit load, in step c), is deposited in a waiting location assigned to the target region in accordance with the order, provided that the target region in accordance with the order is occupied by another autonomous guided vehicle or a waiting location located closer to the target region is occupied by another autonomous guided vehicle or another unit load. The unit load is then received by an autonomous guided vehicle exiting the target region and deposited at a vacant storage location of the target region in accordance with the order. Steps d) and e) will then be obsolete for the originally assigned guided vehicle, and/or the assignment of a transport order is transferred, in this case, from one guided vehicle to another, in particular to the autonomous guided vehicle exiting the target region. In this manner, it is avoided that guided vehicles are occupied by a unit load for an excessively long period of time. Consequently, a relatively small number of guided vehicles can carry out a large number of transport orders.

It is also favorable if the transport system has a primary waiting zone and a secondary waiting zone spaced apart from the primary waiting zone, wherein the waiting locations of the primary waiting zone are statically assigned to one target region each, whereas waiting locations of the secondary waiting zone are dynamically assigned to a target region. The provisioning of a secondary waiting zone enables in particular also the realization of transport systems in which there is only little space available in front of the target regions. In this case, an autonomous guided vehicle travels to a waiting location of the secondary waiting zone and then advances to a waiting location of the primary waiting zone as soon as it is its turn. The physical proximity of the primary waiting zone to the target region ensures that the target region can be occupied by unit loads swiftly.

It is further favorable if the number ANZ of the waiting locations assigned to a target region meets the condition

$$1 \leq ANZ \leq {n}_{L} - 1$$

wherein n_{L} is a number of the storage locations in the target region. In this manner, it is ensured that all autonomous guided vehicles provided for occupying the storage locations which require a waiting location will find one. Another factor for the number of the waiting locations can be, for example, a dwell time of the unit loads in the target region.

It is also conceivable that
the assignment of a unit load to a storage location is done according to a specified order until such time as an assigned abort criterion is met and
the assignment of a unit load to a storage location is derived from an arrival of the autonomous guided vehicles at the target region, which arrival takes place in an unplanned order, but does otherwise not follow any specified order as soon as said abort criterion is met.

In particular, it can be provided here that the abort criterion is met if
the number of the autonomous guided vehicles occupied by a unit load exceeds a first threshold value,
all waiting locations are occupied by autonomous guided vehicles,
a density of autonomous guided vehicles in the travel area exceeds a second threshold value or
the target region is emptied.

In this manner, the storage locations in the target region are occupied according to a specified order unless this is overly disadvantageous for the remaining operations in the transport system, in particular for its performance.

It should also be noted in this context that the variants and advantages disclosed in relation to the method presented equally relate to the transport system presented, and vice versa.

For the purpose of better understanding of the invention, it will be elucidated in more detail by means of the figures below.

The figures show in a respectively very simplified schematic representation:

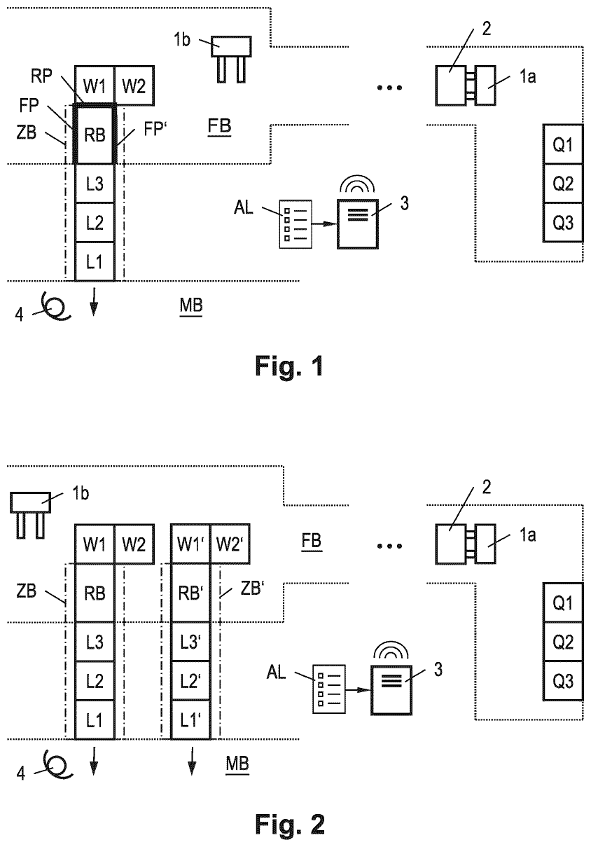

FIG. 1 a first schematically represented example of a transport system with a target region;

FIG. 2 a second schematically represented example of a transport system with two target regions;

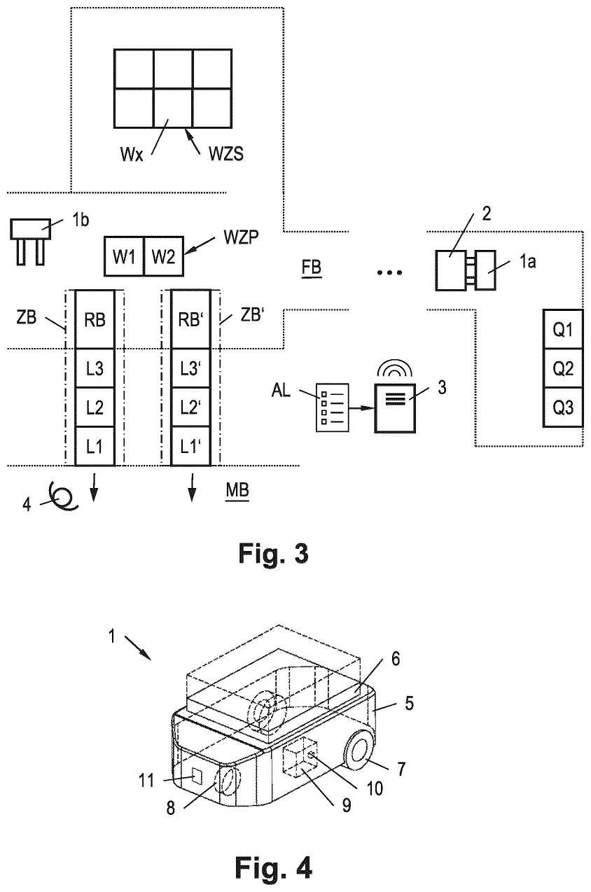

FIG. 3 another schematically represented example of a transport system with a secondary waiting zone and

FIG. 4 an exemplary and schematically represented autonomous guided vehicle in an oblique view.

First of all, it is to be noted that, in the different embodiments described, equal parts are provided with equal reference numbers and/or equal component designations, where the disclosures contained in the entire description may be analogously transferred to equal parts with equal reference numbers and/or equal component designations. Moreover, the specifications of location, such as at the top, at the bottom, at the side, chosen in the description refer to the directly described and depicted figure, and, in case of a change of position, are to be analogously transferred to the new position.

FIG. 1 shows a first schematically represented example of a transport system with a plurality of autonomous guided vehicles 1a, 1b for transporting unit loads 2. The transport system further comprises multiple source positions Q1 . . . Q3, at which unit loads 2 can be provisioned, as well as a target region ZB with multiple storage locations L1 . . . L3 for one unit load each 2. Between the source position Q1 . . . Q3 and the target region ZB, the transport system comprises a travel area FB, which can be traveled on by the plurality of autonomous guided vehicles 1a, 1b. In the travel area FB, multiple waiting locations W1, W2 for the autonomous guided vehicles 1a, 1b are arranged, which waiting locations W1, W2 are assigned to the target region ZB. The transport system further comprises an electronic control system with a control computer 3. In the configuration represented, a worker 4 is located in a manual working area MB.

The functioning of the transport system represented in FIG. 1 is as follows:

In a first step a), multiple transport orders, which are symbolically represented in FIG. 1 by the order list AL, are acquired by the electronic control system, in particular by the control computer 3 or an order-processing computer connected to same. Each transport order contains a source position Q1 . . . Q3, from which a unit load 2 is to be picked up, and a target region ZB, in which the unit load 2 is to be deposited. Optionally, the transport order can additionally also contain the unit load 2 to be transported.

In another step b), a transport order each is assigned to an autonomous guided vehicle 1a, 1b each. For example, this can be done such that an autonomous guided vehicle 1a, 1b independently accepts a transport order, or such that a transport order is assigned to an autonomous guided vehicle 1a, 1b by the control computer 3. Subsequently, the transport order is executed autonomously by the autonomous guided vehicle 1a, 1b.

To that end, the unit load 2 is picked up, in a step c), from the source position Q1 . . . Q3 in accordance with the order by the respective guided vehicle 1a, 1b and transported to a waiting location W1, W2 assigned to the target region ZB in accordance with the order. In the example represented in FIG. 1, the unit load 2 is transported specifically by the autonomous guided vehicle 1a.

In another step d), an accessibility status of the target region ZB is verified. The accessibility status is “occupied” if the target region ZB is occupied by another autonomous guided vehicle 1a, and “unoccupied” if the target region ZB is free from another autonomous guided vehicle 1a. The verification can be done by the autonomous guided vehicle 1a itself and/or by the control computer 3.

If the verification in step d) yields that the accessibility status is “unoccupied,” the autonomous guided vehicle 1a, in a step e), enters the target region ZB in accordance with the order and deposits the unit load 2 at a vacant storage location L1 . . . L3 of the target region ZB in accordance with the order, which vacant storage location L1 . . . L3 is assigned to the unit load 2. If the verification in step d) yields that the accessibility status is “occupied,” it can be provided that the autonomous guided vehicle 1a travels to the vacant waiting location W1, W2 that is located closest to the target region ZB. In this example, this is the waiting location W1.

In a step f), the autonomous guided vehicle 1a exits the target region ZB in accordance with the order. In particular, after exiting the target region ZB, the assigned autonomous guided vehicle 1a can execute a next order, in particular an order according to step a), yet it can also travel to a loading station, for example. The steps c) to f) are carried out for or by multiple autonomous guided vehicles 1a, 1b.

An assignment of a unit load 2 to a vacant storage location L1 . . . L3 is not permanently specified but depends on the arrival of the autonomous guided vehicles 1a, 1b in the target region ZB, in particular on an arrival taking place in an unplanned order. This means that the first unit load 2 is deposited in the target region ZB by the autonomous guided vehicle 1a that arrives at the target region ZB first (not necessarily as planned). Here, the time of the arrival is in particular influenced by the distance of the source position Q1 . . . Q3 to the target region ZB in accordance with the order, by the velocity of the autonomous guided vehicle 1a, 1b and by the events occurring on the transport route. Such an event can be, for example, an unplanned halt of the autonomous guided vehicle 1a, 1b due to an imminent collision with another object.

Preferably, the travel area comprises a reservation position RP and two release positions FP, FP′, such as this is the case in the example represented in FIG. 1. When the autonomous guided vehicle 1a, 1b travels over the reservation position RP in step e), the accessibility status of the target region ZB is changed from “unoccupied” to “occupied.” When the autonomous guided vehicle 1a, 1b travels over either of the two release positions FP, FP′ in step f), the accessibility status of the target region ZB is changed from “occupied” to “unoccupied.” The reservation position RP and/or release positions FP, FP′ can comprise a pass-through sensor, for example a light barrier, a camera or a weight sensor, which acquires a passing through the respective position by the autonomous guided vehicle 1a, 1b. It is also conceivable that a joint reservation and release position is provided, i.e. the reservation position RP and the release positions FP, FP′ can be arranged at the same location and/or at overlapping locations. The fact that the accessibility status is changed when the reservation position RP is traveled over means that an assignment of a unit load 2 to a vacant storage location L1 . . . L3, strictly speaking, depends on the arrival of the autonomous guided vehicles 1a, 1b at the reservation position RP and is only subsequently derived from the arrival in the target region ZB. However, the order of the guided vehicles 1a, 1b at the reservation position RP and in the target region ZB is identical.

In the example represented in FIG. 1, it is also provided that the target region ZB has a maneuvering zone RB, which preferably protrudes into the travel area. In this manner, the access to the storage locations L1 . . . L3 is kept clear and it is facilitated for an autonomous guided vehicle 1a, 1b to exit the target region ZB. It can generally be provided that the maneuvering zone RB can be traveled on also by other autonomous guided vehicles 1a, 1b (i.e. not only the guided vehicles that are assigned to a transport order) 1a, 1b, provided that the maneuvering zone RB is vacant.

Advantageously, the unit loads 2 are deposited sequentially at the storage locations L1 . . . L3 by the autonomous guided vehicles 1a, 1b, so that all storage locations can be occupied, in particular starting at a storage location L1 . . . L3 that is most remote from the maneuvering zone RB or waiting location W1. This means that the target region ZB can be completely occupied by unit loads 2 in this manner.

In the example represented, the target region is assigned multiple waiting locations W1, W2. In this manner, it is ensured that multiple autonomous guided vehicles 1a, 1b can wait for an opportunity to enter the target region ZB. Preferably, the number ANZ of the waiting locations W1, W2 assigned to a target region ZB meets the condition

$$1 \leq ANZ \leq {n}_{L} - 1$$

wherein n_{L} specifies the number of the storage locations L1 . . . L3 in the target region ZB. In this manner 1a, 1b, it is ensured that all autonomous guided vehicles 1a, 1b provided for occupying the storage locations L1 . . . L3 which require a waiting location W1, W2 will find one. Another factor for the number of the waiting locations W1, W2 can be, for example, a dwell time of the unit loads 2 in the target region ZB.

As already mentioned, an autonomous guided vehicle 1a, 1b preferably travels to the vacant waiting location W1, W2 that is located closest to the target region ZB. In the present example, therefore, the waiting location W1 is occupied first, the waiting location W2 subsequently. If the first waiting location W1 is vacant, the autonomous guided vehicle 1a, 1b advances to an adjacent vacant waiting location W2 in a direction of target region ZB. In this manner, the waiting locations W1, W2 assigned to the target region ZB form a waiting line. In particular, the traveling to a vacant waiting location W1, W2 and the advancing to a vacant waiting location W2 is carried out by the autonomous guided vehicle 1a, 1b independently, i.e. without a control command of the control computer 3. In the above context, the term “remote” is not necessarily meant in a topological sense, but primarily in terms of organization.

The waiting locations W1, W2 can be acquired in the control computer 3 and be statically assigned to the target region ZB or be dynamically assigned by the control computer 3 as and when needed. It is also conceivable that a waiting location W1, W2 is dynamically created by an autonomous guided vehicle 1a, 1b.

It can generally be provided that the storage locations L1 . . . L3 of the completely occupied target region ZB are re-occupied by unit loads 2 only if the target region ZB was first emptied completely. In this manner, the target region ZB can be alternately released for or blocked against the access by the autonomous guided vehicles 1a, 1b. A target region that is blocked for the autonomous guided vehicles 1a, 1b, however, can be released for the access by workers 4 in the transport system, for example so that the workers 4 can remove unit loads 2 from the target region ZB. In other words, it can be provided that the target region ZB is accessible alternately from the travel area FB or from the manual working area MB.

The target region ZB is completely occupied whenever any and all storage locations L1 . . . L3 are each occupied by a unit load 2 or no vacant storage location L1 . . . L3 is accessible anymore. Accordingly, the target region ZB is deemed completely occupied even if, while there are still vacant storage locations L1 . . . L3 per se, these storage locations L1 . . . L3 can no longer be reached because the route to them is blocked by (a) unit load(s) 2. The target region ZB is completely emptied whenever none of the storage locations L1 . . . L3 is occupied by a unit load 2.

In another advantageous embodiment variant, it can also be provided that, in step c), the unit load 2 is deposited in a waiting location W1, W2 assigned to the target region ZB in accordance with the order, provided that the target region ZB is occupied by another autonomous guided vehicle 1a, 1b, or a waiting location W1, W2 located closer to the target region ZB is occupied by another autonomous guided vehicle 1a, 1b or another unit load 2. In this embodiment variant, the unit load 2 is subsequently received by an autonomous guided vehicle 1a, 1b exiting the target region ZB and deposited at a vacant storage location L1 . . . L3 of the target region ZB. The steps d) and e) will then be obsolete for the originally assigned guided vehicle 1a, 1b, and/or the assignment of a transport order is transferred, in this case, from one guided vehicle 1a, 1b to another. In this manner, it is avoided that guided vehicles 1a, 1b are occupied by a unit load 2 for an excessively long period of time. Consequently, a relatively small number of guided vehicles 1a, 1b can take over a large number of transport orders.

FIG. 2 shows an embodiment variant of a transport system which is very similar to the transport system represented in FIG. 1. Yet, in contrast to the latter, a second target region ZB′ with storage locations L1′ . . . L3′ and a maneuvering zone RB′ is provided. Furthermore, waiting locations W1′, W2′ assigned to the second target region ZB′ are provided. The method process for the transport system from FIG. 2 resembles the method process described in relation to the transport system from FIG. 1, and also the embodiment variants described in relation to the transport system from FIG. 1 and advantages resulting form same can be applied to the transport system from FIG. 2. However, two target regions ZB, ZB′ are available for the assignment of a unit load 2 in this case.

Furthermore, it can be provided that the target regions ZB, ZB′ are alternately occupied and emptied. In accordance with a first embodiment variant, an alternate filling of the target regions is done such that the second target region ZB′ is occupied only once the first target region ZB is completely occupied (or vice versa). Accordingly, an alternate emptying of the target regions ZB, ZB′ in accordance with the first embodiment is done such that the second target region ZB′ is emptied only once the first target region ZB is completely emptied (or vice versa). In a second embodiment variant, the alternate filling of the target regions ZB, ZB′ is done such that the storage locations L1 . . . L3 and L1′ . . . L3′ of different target regions ZB, ZB′ are occupied alternately. In accordance with the second embodiment, also the alternate emptying of the target regions ZB, ZB′ can be done such that the storage locations L1 . . . L3 and L1′ . . . L3′ of the different target regions ZB, ZB′ are emptied alternately. It can also be provided that the filling is done in accordance with the first embodiment and the emptying is done in accordance with the second embodiment or vice versa. In particular, it can be provided in this context that the storage locations L1 . . . L3, L1′ . . . L3′ of a completely occupied target region ZB, ZB′ are re-occupied by unit loads 2 only if the respective target region ZB, ZB was first emptied completely.

In particular, also in the transport system represented in FIG. 2, it can be provided that waiting locations W1, W2, W1′, W2′ are dynamically generated by the control computer 3 or by an autonomous guided vehicle 1a, 1b as and when needed.

FIG. 3 further shows an embodiment variant of a transport system which is very similar to the transport system represented in FIG. 2. Yet, in contrast to the latter, the transport system according to FIG. 3 comprises a primary waiting zone WZP and a secondary waiting zone WZS spaced apart from the primary waiting zone WZP. In particular, it can be provided that the waiting locations W1, W2, W1′, W2′ of the primary waiting zone WZP are statically assigned to one target region ZB, ZB′ each, whereas waiting locations Wx of the secondary waiting zone WZP are dynamically assigned to a target region ZB, ZB′. Yet, it is also conceivable that the waiting locations W1, W2, W1′, W2′ of the primary waiting zone WZP are dynamically assigned to a target region ZB, ZB′ and/or the waiting locations Wx of the secondary waiting zone WZP are statically assigned to a target region ZB, ZB′. It would also be possible that the waiting locations Wx of the secondary waiting zone WZP are not assigned to any target region ZB, ZB′. The provisioning of a secondary waiting zone WZS enables in particular also the realization of transport systems in which there is only little space available in front of the target regions ZB, ZB′. In this case, an autonomous guided vehicle 1a, 1b travels to a waiting location Wx of the secondary waiting zone WZP and then advances to a waiting location W1, W2, W1′, W2′ of the primary waiting zone WZP as soon as it is its turn.

Generally, it is possible in all embodiment variants that a simulation environment is configured on the control computer 3 and virtual twins of the autonomous guided vehicles 1a, 1b exist in the simulation environment. Here, it can be provided that at least the verification in accordance with step d) is executed in the simulation environment. The virtual twins enable even complex control problems to be solved. In particular, the communication of autonomous guided vehicles 1a, 1b, which have no way of communicating with one another in the real world, is enabled via their virtual twins.

As already mentioned, the assignment of a unit load 2 to a storage location L1 . . . L3, L1′ . . . L3′ can be derived (only) from an arrival of the autonomous guided vehicles 1a, 1b at the target region ZB, ZB′, which arrival takes place in an unplanned order, while it does not otherwise follow any specified order.

Yet, it is also conceivable that
the assignment of a unit load 2 to a storage location L1 . . . L3, L1′ . . . L3′ is done according to a specified order until such time as an assigned abort criterion is met and
the assignment of a unit load 2 to a storage location L1 . . . L3, L1′ . . . L3′ is derived from an arrival of the autonomous guided vehicles 1a, 1b at the target region ZB, ZB′, which arrival takes place in an unplanned order, but does otherwise not follow any specified order as soon as said abort criterion is met.

In particular, it can be provided here that the abort criterion is met if
the number of the autonomous guided vehicles 1a, 1b occupied by a unit load 2 exceeds a first threshold value,
all waiting locations W1, W2, W1′, W2′, Wx are occupied by autonomous guided vehicles 1a, 1b,
a density of autonomous guided vehicles 1a, 1b in the travel area FB exceeds a second threshold value or
the target region ZB, ZB′ is emptied.

FIG. 4 finally shows a possible embodiment of an autonomous guided vehicle 1 (“automated guided vehicle,” “AGV” in short, or “automated mobile robot,” “AMR” in short). The autonomous guided vehicle 1 comprises a chassis 5 with a drive unit and, arranged on the chassis 5, an article reception or loading platform 6 for receiving, depositing and transporting a unit load 2 (not represented in FIG. 4) with or without a transport loading aid. It would also be conceivable that the autonomous guided vehicle 1 additionally or alternatively comprises a hanger rod acting as article reception, with which hanging bags, or hanging articles on article transport carriers with coat hangers, or coat hangers with the hanging articles, can be transported.

The drive unit comprises wheels 7, 8 mounted on the chassis 5 so as to be rotatable, at least one of which wheels 7 is coupled with a drive (not represented), and at least one of which wheels 8 is steerable. It is also possible for both wheels 7 to be coupled with the drive and driven by same. Yet the autonomous guided vehicle 1 may also comprise four wheels, two of which wheels are steerable. According to the embodiment shown, the article reception 6 is mounted on the chassis 6 so as to be adjustable between an initial position (marked by solid lines) and a transport position (marked by dashed lines).

In the initial position, a unit load 2 can be traveled underneath in order to receive same. If the article reception 6 is adjusted from the initial position in a direction of the transport position, the unit load 2 can be lifted and subsequently transported. If the article reception 6 is readjusted from the transport position in a direction of the initial position, the unit load 2 can be deposited, or dispensed, again.

The autonomous guided vehicle 1 further comprises a control 9, schematically represented by dashed lines, for controlling/regulating the movements of the autonomous guided vehicle 1. The control 9 can also comprise means for the (wireless) data transfer to and from the autonomous guided vehicle 1. In this way, the autonomous guided vehicle 1 and/or its control 9 can communicate with the electronic control system, in particular with the control computer 3, i.e. receive commands from same and transmit data to same.

Finally, the autonomous guided vehicle 1 comprises sensors for acquiring the surroundings of the autonomous guided vehicle 1 and for spatial orientation. In this example, the autonomous guided vehicle 1 comprises, in a purely illustrative manner, a position and alignment sensor 10 arranged in the control 9, as well as an ultrasonic sensor 11 connected to the control 9. With the help of the position and alignment sensor 10, the control 9 can determine the position and alignment and/or orientation of the autonomous guided vehicle 1. With the help of the ultrasonic sensor 11, obstacles in the travel path of the autonomous guided vehicle 1 can be identified. Further, the control 9 is connected to the drive and the steering system of the autonomous guided vehicle 1.

Finally, it should be noted that the scope of protection is determined by the claims. However, the description and the drawings are to be adduced for construing the claims. Individual features or feature combinations from the different exemplary embodiments shown and described may represent independent inventive solutions. The object underlying the independent inventive solutions may be gathered from the description.

In particular, it should also be noted that, in reality, the depicted devices can also comprise more, or also fewer, components than depicted. In some cases, the shown devices and/or their components may not be depicted to scale and/or be enlarged and/or reduced in size.

Table of reference numbers

| | |
|---|---|
| 1, 1a, 1b | autonomous guided vehicle |
| 2 | unit load |
| 3 | control computer |
| 4 | worker |
| 5 | chassis |
| 6 | loading platform |
| 7 | wheel (driven) |
| 8 | wheel (steerable) |
| 9 | drive control |
| 10 | position and alignment sensor |
| 11 | ultrasonic sensor |
| AL | order list |
| FB | travel area |
| FP, FP' | release position |
| L1 . . . L3, | storage location |
| L1' . . . L3' | |
| MB | manual working area |
| Q1 . . . Q3 | source position |
| RB, RB' | maneuvering zone |
| RP | reservation position |
| W1, W2, W1', | waiting location |
| W2', Wx | |
| WZP | primary waiting zone |
| WZS | secondary waiting zone |
| ZB, ZB' | target region |

1. A method for transporting unit loads (2) from a source position (Q1 . . . Q3) to a target region (ZB, ZB′) by a plurality of autonomous guided vehicles (1, 1a, 1b) in a travel area (FB) located between the source position (Q1 . . . Q3) and the target region (ZB, ZB′), wherein the target region (ZB, ZB′) has multiple storage locations (L1 . . . L3, L1′ . . . L3′) for one unit load each (2) and wherein at least one waiting location (W1, W2, W1′, W2′, Wx) for an autonomous guided vehicle (1, 1a, 1b), which waiting location (W1, W2, W1′, W2′, Wx) is assigned to the target region (ZB, ZB′), is arranged in the travel area (FB), comprising the steps:
a) acquiring multiple transport orders, each of which contains a source position (Q1 . . . Q3), from which a unit load (2) is to be picked up, and a target region (ZB, ZB′), in which the unit load (2) is to be deposited, by an electronic control system, which comprises a control computer (3),
b) assigning a transport order each to an autonomous guided vehicle (1, 1a, 1b) each,
c) picking up a unit load (2) from the source position in accordance with the order (Q1 . . . Q3), and transporting the unit load (2) to a waiting location (W1, W2, W1′, W2′, Wx) assigned to the target region (ZB, ZB′) in accordance with the order by the autonomous guided vehicle (1, 1a, 1b) assigned to the respective transport order in step b),
d) verifying an accessibility status of the target region (ZB, ZB′) in accordance with the order, wherein the accessibility status is “unoccupied” if the target region (ZB, ZB′) is free from another autonomous guided vehicle (1, 1a, 1b),
e) entering the target region (ZB, ZB′) in accordance with the order by the assigned autonomous guided vehicle (1, 1a, 1b) and depositing the unit load (2) at a vacant storage location (L1 . . . L3, L1′ . . . L3′) of the target region (ZB, ZB′) in accordance with the order, which storage location (L1 . . . L3, L1′ . . . L3′) is assigned to the unit load (2), if the verification in step d) yields that the accessibility status is “unoccupied,”
f) exiting the target region (ZB, ZB′) in accordance with the order by the assigned autonomous guided vehicle (1, 1a, 1b),
wherein steps c) to f) are carried out for multiple autonomous guided vehicles (1, 1a, 1b) and
wherein an assignment of a unit load (2) to a vacant storage location (L1 . . . L3, L1′ . . . L3′) is derived from the arrival of the autonomous guided vehicles (1, 1a, 1b) in the target region (ZB, ZB′).

2. The method according to claim 1,
wherein the travel area comprises a reservation position (RP), which is traveled over by the assigned autonomous guided vehicle (1, 1a, 1b) in step e), wherein the accessibility status of the target region (ZB, ZB′) is changed from “unoccupied” to “occupied” as a result of the reservation position (RP) being traveled over, and
wherein the travel area comprises a release position (FP, FP′), which is traveled over by the assigned autonomous guided vehicle (1, 1a, 1b) in step f), wherein the accessibility status of the target region (ZB, ZB′) is changed from “occupied” to “unoccupied” as a result of the release position (FP, FP′) being traveled over.

3. The method according to claim 1,
wherein the target region (ZB, ZB′) has a maneuvering zone (RB), which preferably protrudes into the travel area, and the unit loads (2) are deposited sequentially at the storage locations (L1 . . . L3, L1′ . . . L3′) by the autonomous guided vehicles (1, 1a, 1b).

4. The method according to claim 1, wherein a target region (ZB, ZB′) is assigned multiple waiting locations (W1, W2, W1′, W2′, Wx), which form a waiting line, and an autonomous guided vehicle (1, 1a, 1b) travels to a vacant waiting location (W1, W2, W1′, W2′, Wx) of the waiting line or advances from a waiting location (W1, W2, W1′, W2′, Wx) to a vacant waiting location (W1, W2, W1′, W2′, Wx) next in line.

5. The method according to claim 1, wherein waiting locations (W1, W2, W1′, W2′, Wx)
are acquired in the control computer (3) and are statically assigned to a target region (ZB, ZB′) or are dynamically assigned by the control computer (3) as and when needed, or
are dynamically created by the autonomous guided vehicles.

6. The method according to claim 1, wherein
an autonomous guided vehicle (1, 1a, 1b) independently accepts and autonomously executes a transport order of the transport orders acquired in step a) or
an autonomous guided vehicle (1, 1a, 1b) is assigned a transport order of the transport orders acquired in step a) by the control computer (3), which transport order is autonomously executed by the autonomous guided vehicle (1, 1a, 1b) after receipt.

7. The method according to claim 1, wherein the storage locations (L1 . . . L3, L1′ . . . L3′) of a completely occupied target region (ZB, ZB′) are re-occupied by unit loads (2) only if the respective target region (ZB, ZB′) was first emptied completely.

8. The method according to claim 1, further comprising multiple target regions (ZB, ZB′), which are alternately occupied and emptied.

9. The method according to claim 1, wherein virtual twins of the autonomous guided vehicles (1, 1a, 1b) exist in a simulation environment on the control computer (3) and at least the verification in accordance with step d) is executed in the simulation environment.

10. The method according to claim 1, wherein, in step c), the unit load (2) is deposited in a waiting location (W1, W2, W1′, W2′, Wx) assigned to the target region (ZB, ZB′) in accordance with the order, provided that the target region (ZB, ZB′) in accordance with the order is occupied by another autonomous guided vehicle (1, 1a, 1b), or a waiting location (W1, W2, W1′, W2′, Wx) located closer to the target region (ZB, ZB′) is occupied by another autonomous guided vehicle (1, 1a, 1b) or another unit load (2), and the unit load (2) is received by an autonomous guided vehicle (1, 1a, 1b) exiting the target region (ZB, ZB′) and deposited at a vacant storage location (L1 . . . L3, L1′ . . . L3′) of the target region (ZB, ZB′) in accordance with the order.

11. A transport system for transporting unit loads (2), comprising
a plurality of autonomous guided vehicles (1, 1a, 1b),
an electronic control system, which comprises a control computer (3),
multiple source positions (Q1 . . . Q3), at which unit loads (2) can be provisioned,
a target region (ZB, ZB′) with multiple storage locations (L1 . . . L3, L1′ . . . L3′) for one unit load (2) each,
a travel area (FB) located between the source position (Q1 . . . Q3) and the target region (ZB, ZB′), which can be traveled on by the plurality of autonomous guided vehicles (1, 1a, 1b), and
at least one waiting location (W1, W2, W1′, W2′, Wx) for an autonomous guided vehicle (1, 1a, 1b), which waiting location (W1, W2, W1′, W2′, Wx) is located in the travel area (FB) and assigned to the target region (ZB, ZB′),
wherein the electronic control system is configured for acquiring multiple transport orders, each of which contain a source position (Q1 . . . Q3), from which a unit load (2) is to be picked up, and contain a target region (ZB, ZB′), in which the unit load (2) is to be deposited,
wherein the control computer (3) or the guided vehicles (1, 1a, 1b) are configured for performing an assignment of a transport order each to an autonomous guided vehicle (1, 1a, 1b) each,
wherein the control computer (3) or the guided vehicles (1, 1a, 1b) are configured for verifying an accessibility status of the target region (ZB, ZB′), wherein the accessibility status is “unoccupied” if the target region (ZB, ZB′) is free from another autonomous guided vehicle (1, 1a, 1b), and
wherein the guided vehicles (1, 1a, 1b) are configured for
i) picking up a unit load (2) from the source position (Q1 . . . Q3) in accordance with the order and transporting it to a waiting location (W1, W2, W1′, W2′, Wx) assigned to the target region (ZB, ZB′) in accordance with the order,
ii) entering the target region (ZB, ZB′) in accordance with the order and depositing the unit load (2) at a vacant storage location (L1 . . . L3, L1′ . . . L3′) of the target region (ZB, ZB′) in accordance with the order, which storage location (L1 . . . L3, L1′. . . L3′) is assigned to the unit load (2), if the verification of the accessibility status yields that the accessibility status is “unoccupied,” wherein an assignment of a unit load (2) to a vacant storage location (L1 . . . L3, L1′ . . . L3′) is derived from the arrival of the autonomous guided vehicles (1, 1a, 1b) in the target region (ZB, ZB′), and
iii) exiting the target region (ZB, ZB′) in accordance with the order.

12. The transport system according to claim 11, wherein the travel area comprises a reservation position (RP) and a release position (FP, FP′), which can be traveled over by the autonomous guided vehicles, (1, 1a, 1b), and wherein the control computer (3) or the guided vehicles (1, 1a, 1b) are configured for changing the accessibility status of the target region (ZB, ZB′)
from “unoccupied” to “occupied” as a result of the reservation position (RP) being traveled over and
from “occupied” to “unoccupied” as a result of the release position (FP, FP′) being traveled over.

13. The transport system according to claim 11, wherein the target region (ZB, ZB′) has a maneuvering zone (RB), which preferably protrudes into the travel area.

14. The transport system according to claim 11, further comprising
multiple waiting locations (W1, W2, W1′, W2′, Wx) acquired in the control computer (3) and statically assigned to a target region (ZB, ZB′),
multiple waiting locations (W1, W2, W1′, W2′, Wx) acquired in the control computer (3) and dynamically assigned to a target region (ZB, ZB′) by the control computer (3) or
multiple waiting locations (W1, W2, W1′, W2′, Wx) dynamically created by the autonomous guided vehicles.

15. The transport system according to claim 11, further comprising a simulation environment on the control computer (3), in which virtual twins of the autonomous guided vehicles (1, 1a, 1b) exist, which is configured at least for verifying the accessibility status of the target region (ZB, ZB′).

16. The transport system according to claim 11, further comprising a primary waiting zone (WZP) and a secondary waiting zone (WZS) spaced apart from the primary waiting zone (WZP), wherein the waiting locations (W1, W2, W1′, W2′, Wx) of the primary waiting zone (WZP) are statically assigned to one target region (ZB, ZB′) each, whereas waiting locations (W1, W2, W1′, W2′, Wx) of the secondary waiting zone (WZP) are dynamically assigned to a target region (ZB, ZB′).

17. The transport system according to claim 11, wherein the number ANZ of the waiting locations (W1, W2, W1′, W2′, Wx) assigned to a target region (ZB, ZB′) meets the condition
$$1 \leq ANZ \leq {n}_{L} - 1$$
wherein n_{L} is a number of the storage locations (L1 . . . L3, L1′ . . . L3′) in the target region (ZB, ZB′).
